(19) United States
(12) Patent Application Publication
(10) Pub. No.: US 2026/0040993 A1
(43) Pub. Date: Feb. 5, 2026

(54) ELECTRONIC CHIPS

(71) Applicants: STMicroelectronics International N.V., Geneva (CH); UNIVERSITE DE TOURS, Tours (FR)

(72) Inventors: Michael DE CRUZ, Monnaie (FR); Quentin PAOLI, Tours (FR); Daniel ALQUIER, Tours (FR)

(73) Assignees: STMicroelectronics International N.V., Geneva (CH); UNIVERSITE DE TOURS, Tours (FR)

(21) Appl. No.: 19/263,159

(22) Filed: Jul. 8, 2025

(30) Foreign Application Priority Data
Jul. 31, 2024 (FR) FR2408461

(51) Int. Cl. H01L 23/31; C23C 16/02; C23C 16/455; H01L 21/56; H01L 23/00; H01L 23/29

(52) U.S. Cl. CPC H01L 23/3171; C23C 16/0254; C23C 16/45597; H01L 21/561; H01L 23/293; H01L 24/02; H01L 24/81; H01L 2224/022; H01L 2224/81801

(57) ABSTRACT

An electronic chip including a semiconductor substrate in and on which an integrated circuit is formed at least one connection metallization of the integrated circuit formed on the side of a front face of the semiconductor substrate and a first passivation layer covering the front face of the semiconductor substrate, the first passivation layer including openings in line with the connection metallization of the integrated circuit The chip having a second passivation layer covering the side flanks of the semiconductor substrate, the second passivation layer being made of a parylene, and the first passivation layer and the second passivation layer being in contact with each other on the side of the front face of the semiconductor substrate. Methods of making a device are also provided.

### CROSS-REFERENCE TO RELATED APPLICATION(S)

This application claims the priority benefit of French patent application number 2408461, filed on Jul. 31, 2024, entitled “Puces électroniques” which is hereby incorporated by reference to the maximum extent allowable by law.

### BACKGROUND

### Technical Field

The present disclosure relates generally to manufacturing electronic chips and more particularly manufacturing so-called surface-mounted electronic chips, i.e., including on a side of a connection face, one or more corresponding connection metallization intended to be brazed at corresponding connecting ranges located on a connection face of an outer device, for example a printed circuit board or another chip.

### Description of the Related Art

Conventionally, connection metallization of a surface-mounted chip is disposed on the side of the face of the chip facing the connection face of the outer device. To ensure the electrical reliability of the electronic chip, and to avoid short-circuit, specifically at the end of brazing the chip on the outer device, the connection face of the electronic chip could be electrically insulated by a passivation layer formed around the contact metallization. For some applications, it is desirable to electrically insulate, in addition to the connection face, the side flanks of the electronic chip.

There is a need to improve the electronic chips.

### BRIEF SUMMARY

To this end, one embodiment provides an electronic chip including a semiconductor substrate in and on which an integrated circuit is formed, at least one connection metallization of the integrated circuit formed on the side of a front face of the semiconductor substrate, a first passivation layer covering the front face of the semiconductor substrate, the first passivation layer including openings in line with the connection metallization of the integrated circuit, and a second passivation layer covering the side flanks of the semiconductor substrate, the second passivation layer being made of a parylene, and the first passivation layer and the second passivation layer being in contact with each other on the side of the front face of the semiconductor substrate.

According to an embodiment, the second passivation layer is made of parylene-N.

According to an embodiment, the second passivation layer is made of parylene-C.

According to an embodiment, the second passivation layer is made of parylene-AF4.

According to an embodiment, a back face of the semiconductor substrate, opposite the front face of the semiconductor substrate, is covered by the second passivation layer.

Another embodiment provides a method for manufacturing a plurality of electronic chips from a structure including a plurality of integrated circuits formed in and on a semiconductor substrate, at least one connection metallization per integrated circuit formed on the side of a front face of the semiconductor substrate, and a first passivation layer covering the front face of the semiconductor substrate, the first passivation layer including openings in line with the connection metallization of the integrated circuits. The method comprising a step of depositing a second passivation layer on the side flanks of the semiconductor substrate, the second passivation layer being made of a parylene, and the first passivation layer and the second passivation layer being in contact on the side of the front face of the semiconductor substrate.

According to an embodiment, the step of depositing the second passivation layer comprises a vaporization step during which solid dimers of parylene are heated and vaporized into a dimer gas, a pyrolysis step during which the dimer gas is processed by pyrolysis to transform the dimers in their monomer forms, and a depositing step during which the monomer gas deposits on all exposed surfaces.

According to an embodiment, during the step of depositing the second passivation layer, the second passivation layer is deposited on the back face of the semiconductor substrate.

According to an embodiment, the step of depositing the second passivation layer is preceded by a step of forming first trenches in the semiconductor substrate.

According to an embodiment, first trenches are not passing through, and are formed from the front face of the semiconductor substrate, and the step of forming first trenches is followed by a step of forming openings in the semiconductor substrate, from the back face of the semiconductor substrate, opposite first trenches.

According to an embodiment, the step of depositing the second passivation layer is followed by a step of forming second trenches opposite the first trenches, so that individual electronic chips are formed.

Another embodiment provides a method for using an electronic chip mentioned above, including a step of transferring the electronic chip, on the side of its connection metallization, to a metallization of an outer device, the transferring step consisting in depositing a brazing material on the metallization of the outer device, and then in compressing the electronic chip on the outer device.

In at least one embodiment, a device is provided comprising an electronic chip including a substrate having a first surface and a second surface, the first surface transverse the second surface; a first passivation layer on the first surface of the substrate; at least one connection metallization on the first surface of the substrate and extending through the first passivation layer, the at least one connection metallization having a third surface and a fourth surface, the third surface transverse the fourth surface, the third opposite the first surface, the first passivation layer being on portions of the third surface; and a second passivation layer on the second surface of the substrate and the first passivation layer. A method of making the device is provided, including a step of forming the second passivation layer by depositing parylene in a gaseous state at room temperature to fill trenches in the first passivation layer, substrate, or combination thereof.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is a sectional, partial, and schematic view showing an example surface-mounted electronic chip according to one embodiment;

FIG. 2, FIG. 3A, FIG. 3B, FIG. 4A, FIG. 4B, FIG. 5A, FIG. 5B, FIG. 6, and FIG. 7 are each a sectional or perspective view of a structure obtained at the end of a step of a method for manufacturing the electronic chip shown in FIG. 1, according to a first embodiment;

FIG. 8A, FIG. 8B, FIG. 9A, and FIG. 9B are each a sectional or perspective view of a structure obtained at the end of a step of a method for manufacturing the electronic chip shown in FIG. 1, according to a second embodiment; and

FIG. 10, FIG. 11, FIG. 12, FIG. 13, FIG. 14, and FIG. 15 are each a sectional or perspective view of a structure obtained at the end of a step of a method for manufacturing the electronic chip shown in FIG. 1, according to a third embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the implementation of the integrated circuits present in the described electronic chips has not been described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10% or within 10°, and preferably within 5% or within 5°.

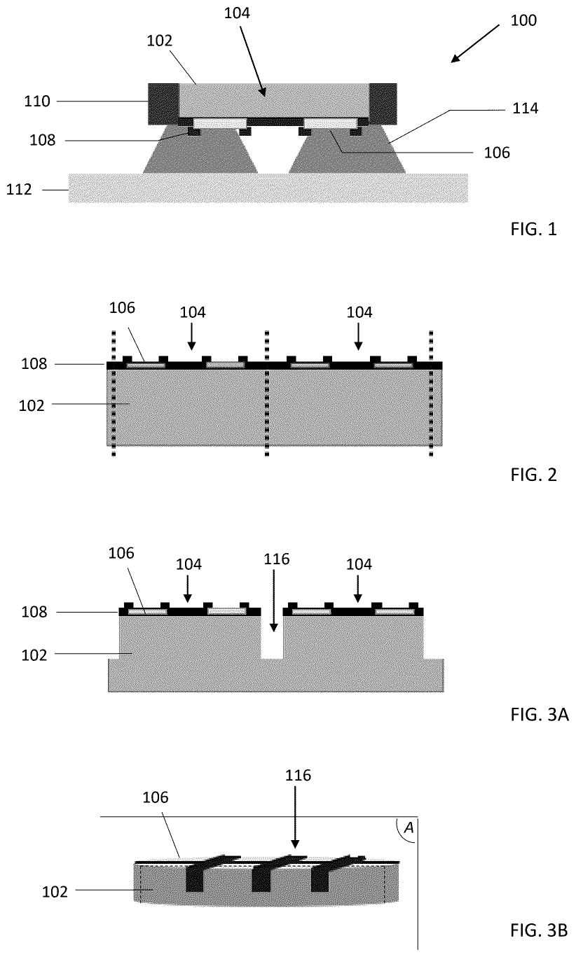

FIG. 1 is a sectional, partial, and schematic view showing an example surface-mounted electronic chip 100 according to one embodiment.

The electronic chip 100 comprises a semiconductor substrate 102 in and on which integrated circuit(s) 104 is (are) formed. The substrate 102 is made of a semiconductor material, for example silicon. For example, the substrate 102 has a thickness within the range from 50 μm to 1400 μm, for example a thickness in the order of 400 μm.

Substrate 102 is for example parallelepiped shaped or rectangular.

For example, each integrated circuit 104 comprises one or more electronic components (transistors, diodes, thyristors, triacs, etc.).

Substrate 102 and integrated circuit 104 are for example overlaid by a stack of insulating and conductive layers referred to as interconnection stack, in which interconnection elements of the components of the circuit 104 could be formed. In particular, the interconnection stack comprises, for each integrated circuit 104, one or more connection metallization 106 formed, in the orientation shown in FIG. 1, on the side of the bottom face of the semiconductor substrate 102, and intended to be connected to an outer device 112.

As an example, connection metallization 106 are made of copper.

In the example shown in FIG. 1, two connection metallization 106 are illustrated. However, the number of connection metallization 106 per chip 100 could be different from two, for example higher than two.

In addition, the electronic chip 100 includes a first passivation layer 108 covering the bottom face of the semiconductor substrate 102. More particularly, the passivation layer 108 covers the whole portions of the bottom face of the substrate 102 not covered by the connection metallization 106. The first passivation layer 108 includes openings in line with connection metallization 106 of the integrated circuit 104. As an example, the first passivation layer 108 covers the side flanks or lateral surfaces of the connection metallization 106. As an example, the first passivation layer 108 further covers the perimeter of the bottom face of the connection metallization 106. In other words, the first passivation layer 108 extends on lateral surfaces and portions of bottom surfaces of the connection metallization 106.

For example, the passivation layer 108 is made of an electrically insulating material, for example made of a dielectric material. As an example, the passivation layer 108 is made of a nitride or a polyimide, for example made of silicon nitride.

For example, the passivation layer 108 has a thickness within the range from 10 nm to 15 μm, for example a thickness in the order of 5 μm.

The electronic chip 100 further includes a second passivation layer 110 covering the side flanks of the semiconductor substrate 102.

The second passivation layer 110 is made of a parylene. As an example, the passivation layer 110 is made of parylene-N((—C₈H₈—)ₙ) or of parylene-C((—C₈H₇Cl—)ₙ). Alternatively, the passivation layer 110 is made of parylene-AF4. ((—CF₂—C₆H₄—CF₂—)ₙ), marketed under the name parylene-HT®.

The passivation layer 110 is deposited with a thickness for example within the range from 50 nm to 60 μm, for example a thickness in the order of 2 μm.

On the side of the bottom face of the semiconductor substrate 102, the first passivation layer 108 is in contact, via its side flank, with the second passivation layer 110.

In FIG. 1, the electronic chip 100 is mounted on the outer device 112. The outer device 112 is for example a printed circuit board or PCB, or another electronic component.

The electrical and mechanical connection between the chip 100 and the outer device 112 is established by a brazing or conductive material 114. Indeed, the chip 100 is electrically and mechanically connected, via its bottom face in the orientation shown in FIG. 1, with the outer device 112. For example, the brazing material 114 is a tin-based material, for example a tin- and silver-based material.

In the example shown in FIG. 1, the brazing material is formed at the interface between each connection metallization 106 of the electronic chip 100 and a not-shown metallization of the outer device 112.

In the following description, one considers as being the front face of the substrate 102 the face supporting the connection metallization 106, for example the bottom face of the substrate 102 in FIG. 1, and as being the back face of the substrate 102 the face opposite the front face, for example the top face of the substrate in FIG. 1. In the following description, it is further considered that the front face of the structure considered corresponds to the face located on the side of the front face of the substrate 102, and that the back face of the structure considered corresponds to the face located on the side of the back face of the substrate 102.

One advantage of the present embodiment is it allows the risks of mechanical contact between the brazing material 114 and the substrate 102 to be limited, specifically on the side of the side flanks of the substrate 102.

Another advantage of the present embodiment is it allows the risks of short-circuit of the chip 100 to be limited.

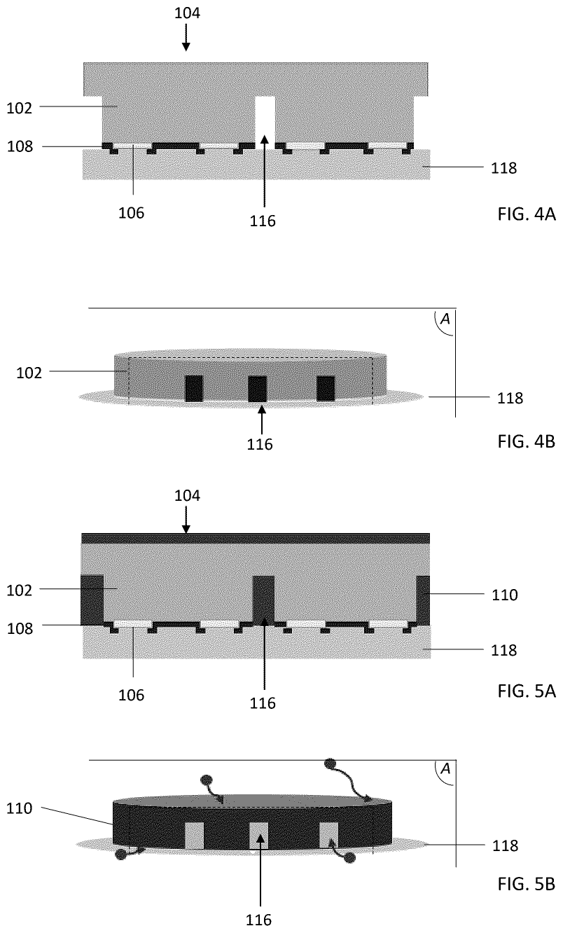

FIG. 2, FIG. 3A, FIG. 3B, FIG. 4A, FIG. 4B, FIG. 5A, FIG. 5B, FIG. 6, and FIG. 7 are each a sectional or perspective view of a structure obtained at the end of a step of a method for manufacturing the electronic chip shown in FIG. 1, according to a first embodiment.

More particularly, FIG. 2 illustrates a starting structure in which several integrated circuits 104 were formed in and on the substrate 102. The structure shown in FIG. 2 includes the connection metallization 106 of the integrated circuits 104 and the passivation layer 108 extending over the front face of the substrate 102.

In the starting structure, the substrate 102 could correspond to a plate made of a semiconductor material, for example a round plate with a diameter of 300 mm or 200 mm.

In FIG. 2, the integrated circuits 104 are schematically illustrated separated from each other by dotted lines.

In FIG. 2, two integrated circuits 104 were illustrated, given that practically the number of integrated circuits 104 formed in and on the substrate 102 of the starting structure could be different from two, for example higher than two.

FIGS. 3A and 3B illustrate a structure obtained at the end of a step of forming trenches 116 in the structure shown in FIG. 2, FIG. 3B being a perspective view and FIG. 3A being a sectional view according to the sectional plane A shown in FIG. 3B.

Trenches 116 are during this step formed from the front face of the structure illustrated in FIG. 2, and extend through the thickness of the substrate 102 by passing through the passivation layer 108. As an example, trenches 116 extend over a depth higher than the depth of the integrated circuits 104. For example, trenches 116 are not passing through, and do not open on the back face of the substrate 102.

As an example, trenches 116 form, when viewed from above, a grid, for example orthogonal, delimiting the integrated circuits 104 formed in and on the substrate 102. At the end of this step, each integrated circuit 104 is for example separated from the neighboring integrated circuits 104 by a trench 116.

As an example, trenches 116 are formed by sawing.

As an example, each trench 116 has a width within the range from 1 μm to 100 μm, for example a width in the order of 50 μm. As an example, each trench has a depth within the range from 100 μm to 400 μm, for example a depth in the order of 200 μm.

FIGS. 4A and 4B illustrate a structure obtained at the end of a step of flipping the structure illustrated in FIGS. 3A and 3B, and of transferring it to a support film 118, FIG. 4B being a perspective view and FIG. 4A being a sectional view according to the sectional plane A shown in FIG. 4B.

More particularly, during this step, the structure illustrated in FIGS. 3A and 3B is flipped, and transferred to the support film 118 so that at the end of this step, the connection metallization 106 are in contact with the support film 118. The connection metallization 106 are then for the next steps unexposed and protected.

For example, the support film 118 is made of a polymer.

FIGS. 5A and 5B illustrate a structure obtained at the end of a step of depositing a layer 110 made of parylene, for example parylene-N, on the whole surfaces of the structure illustrated in FIGS. 4A and 4B, FIG. 5B being a perspective view and FIG. 5A being a sectional view according to the sectional plane A shown in FIG. 5B.

As an example, depositing layer 110 includes a first vaporization step during which solid dimers of parylene, for example (2,2) paracyclophane dimers, are heated and vaporized into a dimer gas. As an example, this step is performed at a temperature of around 175° C.

As an example, depositing layer 110 includes a second step during which the dimer gas is processed by pyrolysis to transform the dimers into their monomer forms. For example, pyrolysis is performed at around 690° C. As an example, during this step, the simple carbon-carbon links linking the two monomers of the parylene dimers break. Double carbon-carbon links are then formed on either side of the aromatic cycle, so as to obtain p-xylylene, for example.

As an example, depositing layer 110 includes a third step during which, within a deposit chamber, the monomer gas deposits on all surfaces exposed of the structure illustrated in FIGS. 4A and 4B. As an example, this step is performed at ambient temperature, for example at a temperature within the range from 10° C. to 30° C. As an example, during this step, in order to reach inside the whole trenches 116, and specifically parts of trenches 116 located at the center of the substrate 102, monomer gas introduces in the grid formed by trenches 116 from the trenches 116 opening on the perimeter of substrate 102.

As an example, a cold trap having for example a temperature of −90° C., is connected to the deposit chamber so as to protect the pump allowing the void to be performed by trapping the volatile residues.

As an example, all of these steps are performed under primary void or vacuum.

As an example, during the depositing step, the layer 110 is gradually deposited so that, first of all, a thin parylene layer covers all exposed surfaces of the structure illustrated in FIGS. 4A and 4B. When the whole structure is covered by the aforementioned thin layer, and the depositing step goes on, the parylene layer thickens until trenches 116 are filled. Layer 110 further covers the back face and side flanks of the structure illustrated in FIGS. 4A and 4B.

FIG. 6 illustrates, with a sectional view, a structure obtained at the end of a step of thinning the structure illustrated in FIGS. 5A and 5B, from its back face.

More particularly, the structure illustrated in FIGS. 5A and 5B is for example thinned from its back face, i.e., the top face in the orientation shown in FIG. 5A. During this step, a portion of the back face of the substrate 102 and the part of layer 110 that has been formed on the back face of the substrate 102 are removed. For example, this step is stopped when the part of layer 110 formed in the bottom of trenches 116 is exposed. As an example, the thinning step is stopped when the integrated circuits are no more mechanically maintained together by a semiconductor material. As an example, the thinning step is stopped before reaching the back face of the integrated circuits. As an example, the thinning is performed by mechanical polishing or chemical mechanical polishing (CMP).

FIG. 7 illustrates, with a sectional view, a structure obtained at the end of a step of individualizing the integrated circuits 104.

More particularly, this step corresponds to forming trenches 120 in the structure illustrated in FIG. 6 so as to form individual chips 100, each chip 100 including a single integrated circuit 104, for example. Trenches 120 are formed opposite the trenches 116 filled by the layer 110, and for example are aligned with them. Trenches 120 are passing through, i.e., they pass through the whole thickness of the substrate 102 so as to open on the top face of the support film 118. Trenches 120 have a width strictly less than the width of trenches 116 so that layer 110 remains on the side flanks of the substrate 102 on either side of trenches 120. As an example, trenches 120 have a width within the range from 1 μm to 60 μm, for example a width in the order of 17 μm.

As an example, trenches 120 are formed by sawing.

As an example, chips 100 could at the end of this step be picked up from the support film 118, and transferred to, and brazed on, the outer device 112 as it was illustrated in FIG. 1. As an example, chips 100 could be transferred by a placing method referred to as “pick and place.”

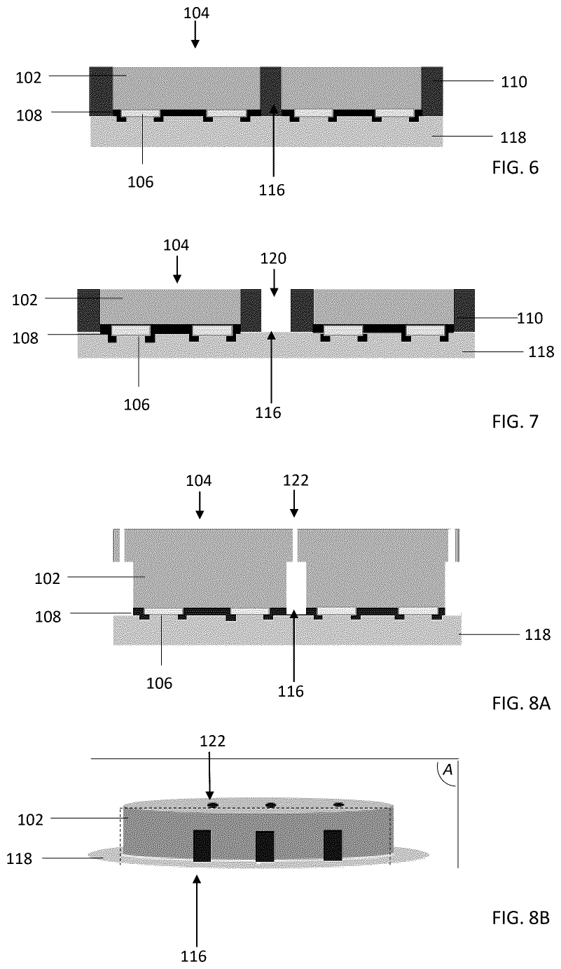

FIG. 8A, FIG. 8B, FIG. 9A, and FIG. 9B are each a sectional or perspective view of a structure obtained at the end of a step of a method for manufacturing the electronic chip 100 illustrated in FIG. 1, according to a second embodiment.

The second embodiment of the method for manufacturing the chip 100 differs from the first embodiment in that it comprises, before depositing the parylene layer 110, forming openings passing through the substrate 102 and opening in the trenches 116. Such openings allow a good penetration of parylene in trenches 116 to be ensured, and thus their correct filling to be secured.

The second embodiment of the method for manufacturing the chip 100 comprises the same first steps as those described in the first embodiment in reference to FIGS. 2 to 4B.

FIGS. 8A and 8B illustrate a structure obtained at the end of a step of forming openings 122 in the structure illustrated in FIGS. 3A and 3B, FIG. 8B being a perspective view and FIG. 8A being a sectional view according to the sectional plane A shown in FIG. 8B.

More particularly, during this step, openings 122 are created opposite some portions of trenches 116. Openings 122 are formed so as to open on the trenches 116 formed during the step illustrated in FIGS. 4A and 4B. As an example, openings 122 are formed, when viewed from above, in a center part of substrate 102.

In the present embodiment, openings 122 are formed from the back face of the substrate 102. Alternatively, one could provide that forming openings 122 is performed from the front face of the substrate 102, before transferring the structure to the support film 118.

For example, openings 122 are circular-shaped, when viewed from above. As an example, openings 122 have a diameter less than, or equal to, the width of trenches 116.

For example, openings 122 are formed by laser ablation.

FIGS. 9A and 9B illustrate a structure obtained at the end of a step of depositing the layer 110 made of parylene on the back face of the structure illustrated in FIGS. 8A and 8B, FIG. 9B being a perspective view and FIG. 9A being a sectional view according to the sectional plane A shown in FIG. 9B.

For example, this step is identical to that was described in reference to FIGS. 5A and 5B, with the difference that filling the trenches 118 with layer 110 is optimized by openings 122.

At the end of this step, the method is, in its second embodiment, identical to that was described in the first embodiment, in reference to FIGS. 6 and 7.

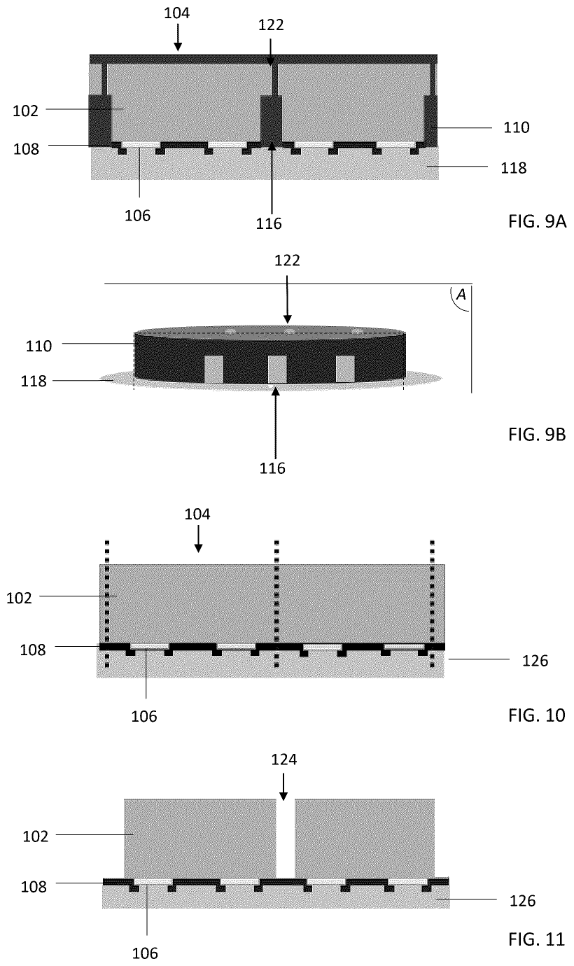

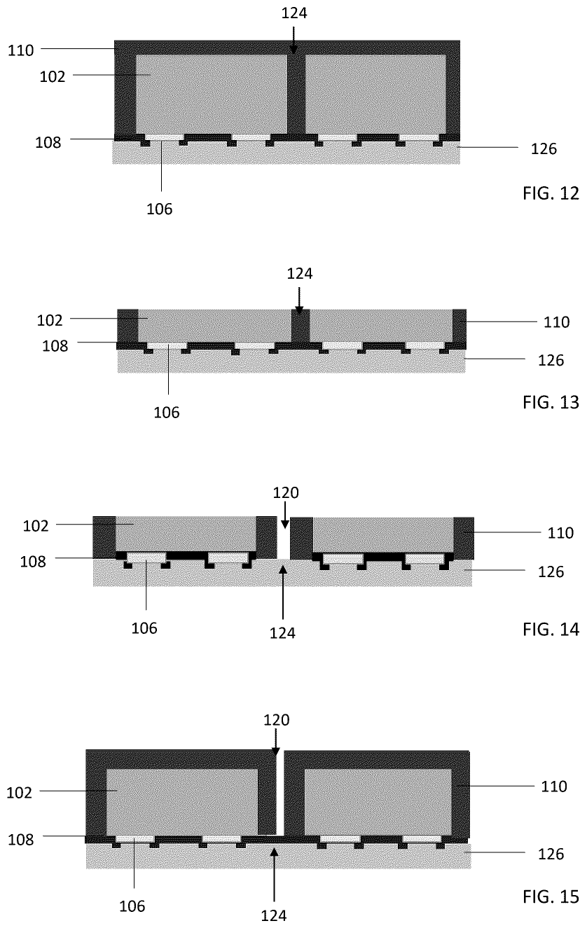

FIG. 10, FIG. 11, FIG. 12, FIG. 13, FIG. 14, and FIG. 15 are each a sectional or perspective view of a structure obtained at the end of a step of a method for manufacturing the electronic chip illustrated in FIG. 1, according to a third embodiment.

The third embodiment of the method for manufacturing the chip 100 differs from the first embodiment in that the step of forming trenches 116 is replaced with a step of forming trenches 124 passing through the whole substrate 102.

FIG. 10 is a sectional view of a starting structure similar to that illustrated in FIG. 2 with the difference that it is mounted, via its front face, on a support film 126. For example, the support film 126 is a film made of polymer.

FIG. 11 is a sectional view of a structure obtained at the end of a step of forming trenches 124 in the structure illustrated in FIG. 10.

More particularly, during this step, trenches 124 are formed so as to pass through the whole thickness of the substrate 102, and to open on the passivation layer 108. Alternatively, trenches 124 pass through the passivation layer 108, and open on the support film 126.

As an example, trenches 124 form, when viewed from above, a grid similar to the grid formed by trenches 116 described in reference to FIGS. 3A and 3B.

As an example, trenches 124 are performed by sawing.

As an example, each trench 124 has a width within the range from 10 μm to 80 μm, for example a width in the order of 28 μm.

As an example, before or after forming trenches 124, the structure could be thinned from its back face so that the thickness of the substrate 102 corresponds to the end thickness of the substrate 102 in the chip 100.

FIG. 12 is a sectional view of a structure obtained at the end of a step of depositing the parylene layer 110 on the top face of the structure illustrated in FIG. 11.

This step is similar to that was described in reference to FIGS. 5A and 5B with the difference that in the present embodiment, trenches 124 are all filled from their back faces.

FIG. 13 and FIG. 14 are sectional views of a structure obtained at the end of steps resulting in individualizing electronic chips 100.

More particularly, FIG. 13 illustrates a structure obtained at the end of a thinning step similar to that described in reference to FIG. 6, with the difference that it is stopped when the thickness desired for chip 100 is reached.

FIG. 14 illustrates a structure obtained at the end of a step of individualizing the integrated circuits 104 by forming trenches 120 in a similar manner as that was described in reference to FIG. 7.

FIG. 15 is a sectional view of a structure obtained at the end of a step of individualizing electronic chips 100 being an alternative to the steps shown in FIGS. 13 and 14.

More particularly, during this step, the thinning step is omitted, and trenches 120 are formed while the parylene layer 110 remains on the back face of the substrate 102.

As an example, during this step, thinning the structure could also be provided, so as to decrease the thickness of the layer 110 on the back face of the substrate 102 without however exposing the back face of the substrate 102.

Numerous applications are likely to benefit from the advantages provided by the electronic chip 100, this chip 100 being thus able to be integrated in various types of components.

As an example, chip 100 could be integrated in a component intended for the automotive industry. Electrifying automotive vehicles causes a high rise in the number of electronic components present inside vehicles. The component for example comprises thyristors, rectifiers, transient voltage suppression diodes, modules, etc., intended to be incorporated in said vehicles. Furthermore, driving assistance and driving automation cause an increase in the number of electronic components inside vehicles. For example, the component comprises transient voltage suppression diodes, electrostatic discharge protection, and common-mode filters allowing the component to be protected against electric hazards.

As an example, the chip 100 could be integrated in a component intended to industry. In particular, the component is for example used in developing green energies, or electrifying infrastructure, for example in charging stations or in collecting solar energy. The component could also be used in the Internet of Things field, or smart home field. For example, the component is intended to be implemented in circuits supplying power to equipment, for example including 800 V or 1,200 V thyristors, 1,200 V ultrafast silicon-carbide diodes, transient voltage suppression diodes, and electrostatic discharge protections. The component could also be used to implement computing systems in cloud, 5G RF communications networks, datacenters, and servers. For example, the component comprises wide band-gap materials.

As an example, the chip 100 could be integrated inside a component intended to be used in personal electronics, for example in order to increase a volume of exchanged information via RF communications, in 5G communications systems, or more generally in any connected component. The component is for example a mobile phone, or smartphone, or is part of an Internet of Things network. The component is for example connected via 5G, via WiFi, or via wide-band communication. For example, the component comprises high rate interfaces, for example with advanced filtering and electrostatic discharge protection.

As an example, the chip 100 could be integrated in a component intended to be used in communications equipment, or in computers and peripherals. For example, the component is used in 5G infrastructures and dedicated datacenters. For example, the component comprises silicon carbide diodes, Schottky power transistors, electrostatic discharge protection, transient voltage suppression diodes. The component could also be used in satellites comprising for example integrated passive devices for RF applications.

In addition, the chip 100 described herein can be integrated into other components and thus have other applications than those mentioned above.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

An electronic chip (100) is summarized as including: a semiconductor substrate (102) in and on which an integrated circuit (104) is formed; at least one connection metallization (106) of the integrated circuit (104) formed on the side of a front face of the semiconductor substrate (102); a first passivation layer (108) covering the front face of the semiconductor substrate (102), the first passivation layer (108) including openings in line with the connection metallization (106) of the integrated circuit (104); and a second passivation layer (110) covering the side flanks of the semiconductor substrate (102), the second passivation layer (110) being made of a parylene, and the first passivation layer (108) and the second passivation layer (110) being in contact with each other on the side of the front face of the semiconductor substrate (102).

The second passivation layer (110) is made of parylene-N.

The second passivation layer (110) is made of parylene-C.

The second passivation layer (110) is made of parylene-AF4.

A back face of the semiconductor substrate (102), opposite the front face of the semiconductor substrate (102), is covered by the second passivation layer (110).

A method for manufacturing a plurality of electronic chips from a structure is summarized as including: a plurality of integrated circuits (104) formed in and on a semiconductor substrate (102); at least one connection metallization (106) per integrated circuit (104) formed on the side of a front face of the semiconductor substrate (102); and a first passivation layer (108) covering the front face of the semiconductor substrate (102), the first passivation layer (108) including openings in line with the connection metallization (106) of the integrated circuits (104), the method including a step of depositing a second passivation layer (110) on the side flanks of the semiconductor substrate (102), the second passivation layer (110) being made of a parylene, and the first passivation layer (108) and the second passivation layer (110) being in contact on the side of the front face of the semiconductor substrate (102).

The step of depositing the second passivation layer (110) includes: a vaporization step during which solid dimers of parylene are heated and vaporized into a dimer gas; a pyrolysis step during which the dimer gas is processed by pyrolysis to transform the dimers in their monomer forms; and a depositing step during which the monomer gas deposits on all exposed surfaces.

During the step of depositing the second passivation layer (110), the second passivation layer (110) is deposited on the back face of the semiconductor substrate (102).

The step of depositing the second passivation layer (110) is preceded by a step of forming first trenches (116; 124) in the semiconductor substrate (102).

First trenches (116; 124) are not passing through, and are formed from the front face of the semiconductor substrate (102), and the step of forming first trenches (116; 124) is followed by a step of forming openings (122) in the semiconductor substrate (102), from the back face of the semiconductor substrate (102), opposite first trenches (116; 124).

The step of depositing the second passivation layer (110) is followed by a step of forming second trenches (120) opposite the first trenches (116; 124), so that individual electronic chips (100) are formed.

A method for using an electronic chip (100) is summarized as including a step of transferring the electronic chip, on the side of its connection metallization (106), to a metallization of an outer device (112), the transferring step consisting in depositing a brazing material (114) on the metallization of the outer device (112), and then in compressing the electronic chip (100) on the outer device (112).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic chip, comprising:
a semiconductor substrate in and on which an integrated circuit is formed;
at least one connection metallization of the integrated circuit formed on a side of a front face of the semiconductor substrate, the at least one connection metallization having a first surface and a second surface, the first surface transverse the second surface;
a first passivation layer covering the front face of the semiconductor substrate, the first passivation layer including openings in line with the connection metallization of the integrated circuit, the first passivation layer being on the first and second surfaces of the at least one connection metallization; and
a second passivation layer covering lateral surfaces of the semiconductor substrate, the second passivation layer being made of a parylene, and the first passivation layer and the second passivation layer being in contact with each other on the side of the front face of the semiconductor substrate.

2. The electronic chip according to claim 1, wherein the second passivation layer is made of parylene-N.

3. The electronic chip according to claim 1, wherein the second passivation layer is made of parylene-C.

4. The electronic chip according to claim 1, wherein the second passivation layer is made of parylene-AF4.

5. The electronic chip according to claim 1, wherein a back face of the semiconductor substrate, opposite the front face of the semiconductor substrate, is covered by the second passivation layer.

6. A method for manufacturing a plurality of electronic chips from a structure, the structure including:
a plurality of integrated circuits formed in and on a semiconductor substrate;
at least one connection metallization per integrated circuit formed on a side of a front face of the semiconductor substrate, the at least one connection metallization having a first surface and a second surface, the first surface transverse the second surface; and
a first passivation layer covering the front face of the semiconductor substrate, the first passivation layer including openings in line with the connection metallization of the integrated circuits, the first passivation layer being on the first and second surfaces of the at least one connection metallization;
the method including a step of depositing a second passivation layer on lateral surfaces of the semiconductor substrate, the second passivation layer being made of a parylene, and the first passivation layer and the second passivation layer being in contact on the side of the front face of the semiconductor substrate.

7. The method according to claim 6, wherein the step of depositing the second passivation layer comprises:
a vaporization step during which solid dimers of parylene are heated and vaporized into a dimer gas;
a pyrolysis step during which the dimer gas is processed by pyrolysis to transform the dimers in their monomer forms, thereby forming a monomer gas; and
a depositing step during which the monomer gas deposits on all exposed surfaces.

8. The method according to claim 6, wherein during the step of depositing the second passivation layer, the second passivation layer is deposited on a back face of the semiconductor substrate.

9. The method according to claim 6, wherein the step of depositing the second passivation layer is preceded by a step of forming first trenches in the semiconductor substrate.

10. The method according to claim 9, wherein first trenches are not passing through, and are formed from the front face of the semiconductor substrate, and the step of forming first trenches is followed by a step of forming openings in the semiconductor substrate, from a back face of the semiconductor substrate, opposite first trenches.

11. The method according to claim 9, wherein the step of depositing the second passivation layer is followed by a step of forming second trenches opposite the first trenches, so that individual electronic chips are formed.

12. A method for using the electronic chip according to claim 1, including a step of transferring the electronic chip, on the side of its connection metallization, to a metallization of an outer device, the transferring step consisting in depositing a brazing material on the metallization of the outer device, and then in compressing the electronic chip on the outer device.

13. A device, comprising:
an electronic chip, including:
a substrate having a first surface and a second surface, the first surface transverse the second surface;
a first passivation layer on the first surface of the substrate;
at least one connection metallization on the first surface of the substrate and extending through the first passivation layer, the at least one connection metallization having a third surface and a fourth surface, the third surface transverse the fourth surface, the third opposite the first surface, the first passivation layer being on portions of the third surface; and
a second passivation layer on the second surface of the substrate and the first passivation layer.

14. The device of claim 13, wherein the substrate is a semiconductor substrate.

15. The device of claim 13, wherein the substrate includes an integrated circuit.

16. The device of claim 13, wherein the at least one connection metallization includes two connection metallization spaced from each other via a portion of the first passivation layer.

17. The device of claim 13, wherein the first passivation layer is on a perimeter of the at least one connection metallization.

18. The device of claim 13, wherein the second surface of the substrate is coplanar with a lateral surface of the first passivation layer, the second passivation layer contacting the second surface of the substrate and the lateral surface of the first passivation layer.

19. The device of claim 13, wherein the third surface of the at least one connection metallization includes a central region exposed from the first passivation layer.

20. The device of claim 13, wherein the second passivation layer is made of parylene.
